(19) United States
(12) Patent Application Publication
(10) Pub. No.: US 2021/0288155 A1
(43) Pub. Date: Sep. 16, 2021

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Kazushiro Nomura, Kawasaki Kanagawa (JP)

(21) Appl. No.: 17/016,461

(22) Filed: Sep. 10, 2020

(30) Foreign Application Priority Data
Mar. 16, 2020 (JP) 2020-045118

(51) Int. Cl. H01L 29/417; H01L 29/45

(52) U.S. Cl. CPC H01L 29/41741; H01L 29/45

(57) ABSTRACT

A semiconductor device according to an embodiment includes a semiconductor substrate including a substrate bottom surface and a substrate upper surface and including a recess in the substrate bottom surface, a semiconductor element provided above the recess, and a first electrode provided in the recess. The recess includes a recess side surface and a recess upper surface, an angle formed between the recess side surface and the recess upper surface is 90 degrees or more, and a film thickness of the first electrode is ½ or more of a depth of the recess.

### CROSS-REFERENCE TO RELATED APPLICATION

This application is based upon and claims the benefit of priority from Japanese Patent Application No.2020-045118, filed on Mar. 16, 2020, the entire contents of which are incorporated herein by reference.

### FIELD

Embodiments described herein relate generally to a semiconductor device.

### BACKGROUND

A power semiconductor chip, such as a metal-oxide-semiconductor field-effect-transistor (MOSFET) and an insulated gate bipolar transistor (IGBT), is being developed designed for power control for a wide variety of fields such as power generation and power transmission, a rotating machine for a pump, a blower, or the like, a power supply device for a communication system, a plant, or the like, a railroad vehicle powered by an alternating-current motor, an electric vehicle, and a household appliance.

Also, a semiconductor device serving as a power module with use of such a power semiconductor chip is being developed. Such a semiconductor device is required to have specifications such as high current density, low loss, and high heat dissipation.

### BRIEF DESCRIPTION OF THE DRAWINGS

FIGS. 1A to 1C are a schematic top view, a schematic cross-sectional view, and a schematic bottom view of a semiconductor device according to a first embodiment;

FIGS. 2A. to 2F are schematic cross-sectional views illustrating the semiconductor device being manufactured in a method for manufacturing the semiconductor device according to the first embodiment;

FIG. 3 is a schematic cross-sectional view of a semiconductor device as a comparative mode with the first embodiment;

FIG. 4 is a schematic cross-sectional view of a semiconductor device according to a second embodiment;

FIGS. 5A and 5E are schematic cross-sectional views of a semiconductor device according to a third embodiment; and

FIG. 6 is a schematic cross-sectional view of a semiconductor device according to a fourth embodiment.

### DETAILED DESCRIPTION

A semiconductor device according to an embodiment includes a semiconductor substrate including a substrate bottom surface and a substrate upper surface and including a recess in the substrate bottom surface, a semiconductor element provided above the recess, and a first electrode provided in the recess. The recess includes a recess side surface and a recess upper surface, an angle formed between the recess side surface and the recess upper surface is 90 degrees or more, and a film thickness of the first electrode is 1/2 or more of a depth of the recess.

Hereinbelow, embodiments of the present disclosure will be described with reference to the drawings. In the following description, similar or identical members may be labeled with the same reference numerals. Also, description of members and the like once described may appropriately be omitted.

In the present specification, in order to illustrate positional relationships among components, an upper direction in the drawings is expressed as “upper” while a lower direction in the drawings is expressed as “lower”. In the present specification, the concepts “upper” and “lower” are not necessarily terms indicating a relationship with the direction of gravity.

### First Embodiment

A semiconductor device according to the present embodiment includes a semiconductor substrate including a substrate bottom surface and a substrate upper surface and including a recess in the substrate bottom surface, a semiconductor element provided above the recess, and a first electrode provided in the recess. The recess includes a recess side surface and a recess upper surface, an angle formed between the recess side surface and the recess upper surface is 90 degrees or more, and a film thickness of the first electrode is 1/2 or more of a depth of the recess.

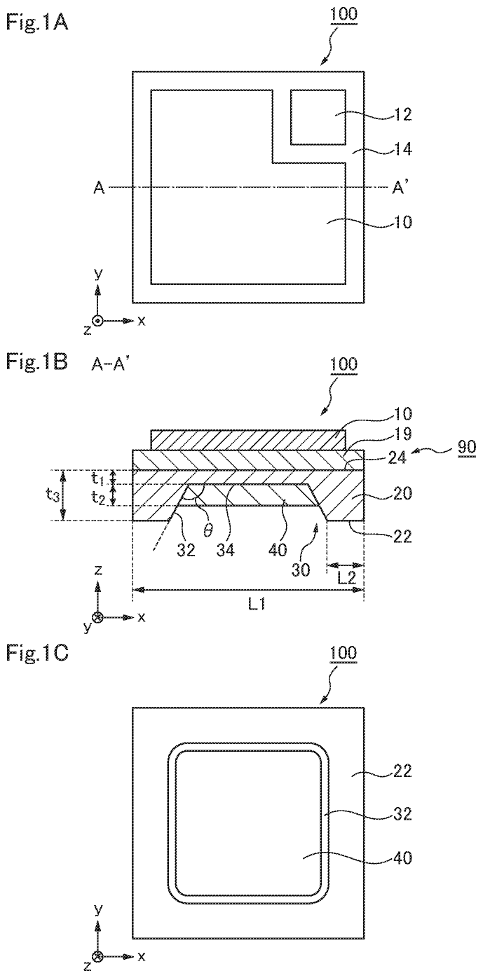

FIGS. 1A to 1C are schematic cross-sectional views of a semiconductor device 100 according to the present embodiment.

FIG. 1A is a schematic top view of the semiconductor device 100 according to the present embodiment. FIG. 1B is a schematic cross-sectional view of the semiconductor device 100 according to the present embodiment. FIG. 1C is a schematic bottom view of the semiconductor device 100 according to the present embodiment.

The semiconductor device 100 according to the present embodiment will be described with reference to FIGS. 1A to 1C.

The semiconductor device 100 includes a semiconductor substrate 20, a semiconductor element 90, and a first electrode 40.

The semiconductor substrate 20 is a silicon (Si) substrate, for example. However, the semiconductor substrate 20 may be a silicon carbide (SiC) substrate, a nitride semiconductor substrate, or another semiconductor substrate.

The semiconductor substrate 20 includes a substrate bottom surface 22 and a substrate upper surface 24. The semiconductor substrate 20 also includes a recess 30 provided in the substrate bottom surface 22. Here, the recess 30 includes a recess side surface 32 and a recess upper surface 34.

A surface of the semiconductor device 100 on a side on which the substrate upper surface 24 is located is referred to as a device surface or an element surface.

As illustrated in FIG. 1C, the recess 30 is provided about a center of the substrate bottom surface 22, for example, and the present disclosure is not limited to this. Also, the substrate bottom surface 22 is provided around the recess 30.

The recess upper surface 34 is preferably parallel to the substrate upper surface 24 to facilitate manufacture of the semiconductor device 100, for example. However, the recess upper surface 31 does not need to be parallel to the substrate upper surface 24.

An angle θ formed between the recess side surface 32 and the recess upper surface 34 is preferably 90 degrees or more.

At least a part of the semiconductor element 90 is provided above the recess 30. Also, a part of the semiconductor element 90 is provided in an element region 19. The semiconductor element 90 according to the present embodiment is an n-type vertical MOSFET, for example. A source electrode 10 is provided above the substrate upper surface 24 via the element region 19. In other words, the source electrode 10 is provided on the element region 19. In a case in which the semiconductor element 90 is a MOSFET, the source electrode 10 functions as a source electrode of the semiconductor element 90.

The first electrode 40 is provided in the recess 30. In a case in which the semiconductor element 90 is a MOSFET, the first electrode 40 functions as a drain electrode of the semiconductor element 90, for example.

Meanwhile, the semiconductor element 90 according to the present embodiment may be a p-type MOSFET, an Si-IGBT, an Si-FRD (Fast Recovery Diode), an SiC-IGBT, an SiC-MOSFET, or an SiC-SBD (Schottky Barrier Diode) using silicon carbide (SiC), a GaN-MOSFET using a nitride semiconductor which is a III-V semiconductor whose group V element is nitrogen, or the like. For example, the MOSFET may be a planar MOSFET or a trench MOSFET. For example, the MOSFET may be a lateral MOSFET. Also, the semiconductor element 90 does not have to be a so-called power semiconductor element.

Each of the first electrode 40 and the source electrode 10 is made of copper (Cu) , silver (Ag) , gold (Au), aluminum (Al), or the like and contains Cu, Ag, Au, or Al. Meanwhile, each of the first electrode 40 and the source electrode 10 may contain another metal such as platinum (Pt), palladium (Pd), tin (Sn), or nickel (Ni).

A film thickness t₂ of the first electrode 40 is preferably longer than a substrate thickness t₁ of a portion of the semiconductor substrate 20 provided with the recess 30 (FIG. 1B). Also, the substrate thickness t₁ of the portion of the semiconductor substrate 20 provided with the recess 30 is preferably 100 μm or shorter (FIG. 1B). Meanwhile, the substrate thickness t₁ of the portion of the semiconductor substrate 20 provided with the recess 30 may be longer than 100 μm. Also, a length. L₂ of a portion of the substrate bottom surface 22 not provided with the recess 30 is preferably 1/4 or less of a length L₁ of the substrate upper surface 24 (FIG. 1B). Further, the length L₂ of the portion of the substrate bottom surface 22 not provided with the recess 30 is preferably 1/10 or less of the length L₁ of the substrate upper surface 24. Further, the film thickness t₂ of the first electrode 40 is preferably 1/2 or more of a depth t₃−t₁ of the recess 30. Note that t₃ is a substrate thickness of the semiconductor substrate 20.

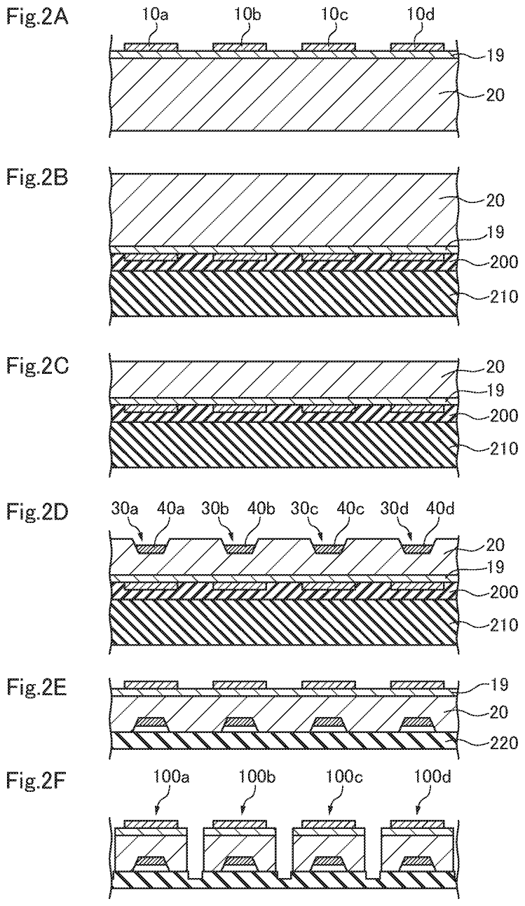

FIGS. 2A to 2F are schematic cross-sectional views illustrating the semiconductor device 100 being manufactured in a method for manufacturing the semiconductor device 100 according to the present embodiment.

First, the element region 19 including a part of the semiconductor element 90 is formed on the semiconductor substrate 20. Subsequently, source electrodes 10a, 10b, 10c, and 10d serving as the source electrode 10 are respectively formed on the element region 19 (FIG. 2A).

Subsequently, a surface on which the source electrodes 10a, 10b, 10c and 10d are formed is secured on a support substrate 210 such as a glass substrate with use of an adhesive 200 (FIG. 2B).

Subsequently, the semiconductor substrate 20 is thinned by means of back grinding or the like (FIG. 2C).

Subsequently, a recess 30a, a recess 30b, a recess 30c, and a recess 30d serving as the recess 30 are formed in the semiconductor substrate 20 by application of photoresist, exposure, development, etching of the semiconductor substrate 20, and removal of the photoresist. Subsequently, a first electrode 40a, a first electrode 40b, a first electrode 40c, and a first electrode 40d serving as the first electrode 40 are formed in the recess 30a, the recess 30b, the recess 30c, and the recess 30d by sputtering or plating, chemical mechanical polishing (CMP), and the like (FIG. 2D). Meanwhile, the plating in the present embodiment may be electrolytic plating or electroless plating.

Subsequently, the semiconductor substrate 20 is peeled from the support substrate 210 and is attached to and secured on a dicing tape 220 (FIG. 2E).

Subsequently, dicing is performed by blade dicing, for example, to obtain a semiconductor device 100a, a semiconductor device 100b, a semiconductor device 100c, and a semiconductor device 100d serving as the semiconductor device 100 (FIG. 2F).

Meanwhile, in FIGS. 2A to 2F, the substrate thickness of the portion of the semiconductor substrate 20 provided with the recess 30 is illustrated to be longer than the film thickness of the first electrode 40. However, as described above, the film thickness of the first electrode 40 is longer than the substrate thickness of the portion of the semiconductor substrate 20 provided with the recess 30.

Next, operational effects of the semiconductor device 100 according to the present embodiment will be described.

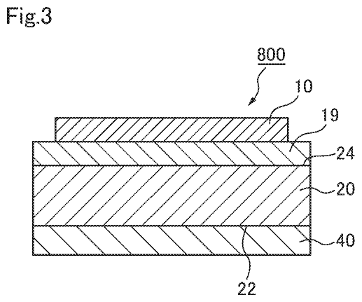

FIG. 3 is a schematic cross-sectional view of a semiconductor device 800 as a comparative mode with the present embodiment. The semiconductor device 800 is not provided with the recess 30. Also, the first electrode 40 is provided over the entire surface of the substrate bottom surface 22.

As in the semiconductor device 800, in a case in which the first electrode 40 is provided over the entire surface of the substrate bottom surface 22, at the time of dicing by means of the blade dicing, self sharpening of the blade while the first electrode 40 is being cut is hard to occur. Therefore, cracking (cracks) and chipping (fine chips) are generated in the semiconductor device 800, which causes a problem of a decrease in mechanical strength and reliability.

Also, in a case of dicing by means of laser, semiconductor materials contained in the semiconductor substrate 20 and metal materials contained in the first electrode 40 are attached to the side surface of the semiconductor device 800 due to vapor deposition. This causes a problem in which mechanical strength and reliability of the semiconductor device 800 are lowered.

Further, in a case in which the first electrode 40 is provided over the entire surface of the substrate bottom surface 22, warpage due to a difference in thermal expansion coefficient between the semiconductor substrate 20 and the first electrode 40 is generated significantly, which causes a problem of difficulty in handling.

The semiconductor device 100 according to the present embodiment includes a semiconductor substrate including a substrate bottom surface and a substrate upper surface and including a recess in the substrate bottom surface, a semiconductor element provided above the recess, and a first electrode provided in the recess. The recess includes a recess side surface and a recess upper surface, an angle formed between the recess side surface and the recess upper surface is 90 degrees or more, and a film thickness of the first electrode is 1/2 or more of a depth of the recess.

The recess 30 is provided in the substrate bottom surface 22, and the first electrode 40 is provided in the recess 30. Therefore, the first electrode 40 does not have to be cut by the blade at the time of the blade dicing. This can suppress generation of cracking and chipping. Accordingly, a highly reliable semiconductor device can be provided.

Also, the angle formed between the recess side surface 32 and the recess upper surface 34 is 90 degrees or more. In a case in which the angle formed between the recess side surface 32 and the recess upper surface 34 is lower than 90 degrees, stress is likely to be applied to an intersection between the recess side surface 32 and the recess upper surface 34 and a periphery of the intersection, and the mechanical strength and reliability will be lowered. Since the angle formed between the recess side surface 32 and the recess upper surface 34 is 90 degrees or more, the semiconductor substrate 20 is free from stress. Accordingly, a highly reliable semiconductor device can be provided.

The film thickness t₂ of the first electrode 40 is preferably longer than the substrate thickness t₁ of a portion of the semiconductor substrate 20 provided with the recess 30. The reason for this is to increase the mechanical strength of the semiconductor device 100 by making the film thickness t₂ of the first electrode 40 longer.

The substrate thickness t₁ of the portion of the semiconductor substrate 20 provided with the recess 30 is preferably 100 μm or shorter. Particularly in such a case, the semiconductor device 100 according to the present embodiment is preferably applied.

The length L₂ of the portion of the substrate bottom surface 22 not provided with the recess 30 is preferably 1/4 or less of the length L₁ of the substrate upper surface 24. The reason for this is to lower the resistance of the semiconductor element 90 by making a portion provided with the first electrode 40 as large as possible.

The film thickness t₂ of the first electrode 40 is preferably 1/2 or more of the depth t₃−t₁ of the recess 30. The reason for this is to increase the mechanical strength of the semiconductor device by making the film thickness of the first electrode 40 as long as possible.

With the semiconductor device 100 according to the present embodiment, a highly reliable semiconductor device can be provided.

### Second Embodiment

A semiconductor device 120 according to the present embodiment differs from the semiconductor device according to the first embodiment in that the first electrode 40 is provided over the recess upper surface 34, the recess side surface 32, and the substrate bottom surface 22. Here, description of contents overlapping with those of the semiconductor device according to the first embodiment is omitted.

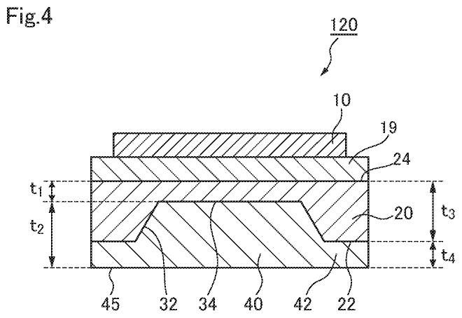

FIG. 4 is a schematic cross-sectional view of the semiconductor device 120 according to the present embodiment.

A portion 42 of the first electrode 40 contacting the substrate bottom surface 22 may be provided. However, preferably, a film thickness t₄ of the portion 42 of the first electrode 40 contacting the substrate bottom surface 22 is not long. Specifically, the film thickness t₂ of the first electrode 40 is preferably longer than twice the film thickness t₄ of the portion of the first electrode 40 contacting the substrate bottom surface 22. The reason for this is that, in a case in which the film thickness t₄ of the portion 42 of the first electrode 40 contacting the substrate bottom surface 22 is too long, at the time of cutting of the portion of the first electrode 40 contacting the substrate bottom surface 22, self sharpening of the blade is hard to occur, and reliability may be lowered, as described above.

A bottom surface 45 of the first electrode is preferably parallel to the substrate upper surface 24 and the substrate bottom surface 22, and the present disclosure is not particularly limited to this.

With the semiconductor device 120 according to the present embodiment as well, a highly reliable semiconductor device can be provided.

### Third Embodiment

Each of a semiconductor device 130 and a semiconductor device 140 according to the present embodiment differs from the semiconductor devices according to the first and second embodiments in that the first electrode 40 includes a first layer 44 containing a first element and a second layer 46 provided on the first layer and containing a second element different from the first element. Also, each of the semiconductor device 130 and the semiconductor device 140 according to the present embodiment differs from the semiconductor devices according to the first and second embodiments in that the first electrode 40 includes a barrier metal at a portion of the first electrode 40 contacting the recess side surface 32 and the recess upper surface 34. Here, description of contents overlapping with those of the semiconductor devices according to the first and second embodiments is omitted.

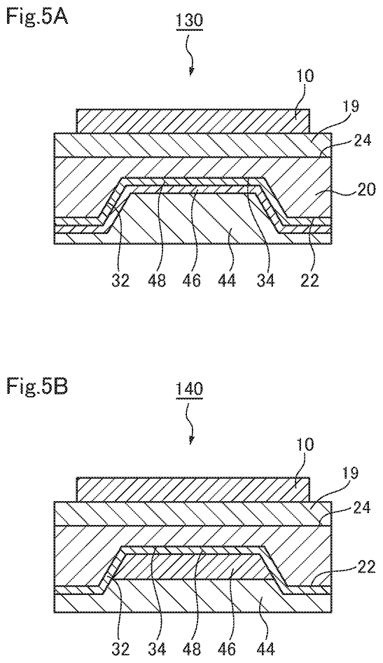

FIGS. 5A and 5B are schematic cross-sectional views of the semiconductor device 130 and the semiconductor device 140 according to the present embodiment. FIG. 5A is a schematic cross-sectional view of the semiconductor device 130 according to the present embodiment, and FIG. 5B is a schematic cross-sectional view of the semiconductor device 140 according to the present embodiment.

The first element and the second element are not particularly limited, but can be selected from elements such as Cu, Ag, Au, Al, Pt, Pd, Sn, or Ni.

The barrier metal 48 is preferably titanium (Ti) or TiNi and is not limited to this.

In the semiconductor device 130 in FIG. 5A, a film thickness of the second layer 46 is substantially uniform. On the other hand, in the semiconductor device 140 in FIG. 5B, a boundary between the first layer 44 and the second layer 46 is parallel to the substrate upper surface 24 or the substrate bottom surface 22. Both of the semiconductor devices can preferably be used.

With the semiconductor device 130 according to the present embodiment as well, a highly reliable semiconductor device can be provided.

### Fourth Embodiment

A semiconductor device 150 according to the present embodiment differs from the semiconductor devices according to the first to third embodiments in that the first electrode 40 further includes a third layer 49 provided between the first layer and the second layer and containing titanium (Ti) or tantalum (Ta). Here, description of contents overlapping with those of the semiconductor devices according to the first to third embodiments is omitted.

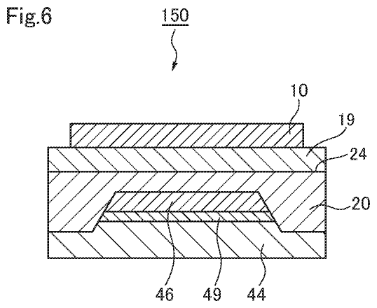

FIG. 6 is a schematic cross-sectional view of the semiconductor device 150 according to the present embodiment.

The third layer 49 is a diffusion prevention layer. Accordingly, since it is possible to suppress mutual diffusion of the first element contained in the first layer 44 and the second element contained in the second layer 46, a more reliable semiconductor device can be provided. Meanwhile, as the third layer 49, an SnAg alloy, a CuSn alloy, or the like can preferably be used.

With the semiconductor device 150 according to the present embodiment as well, a highly reliable semiconductor device can be provided.

While certain embodiments have been described, these embodiments have been presented by way of example only, and are not intended to limit the scope of the inventions. Indeed, the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor substrate including a substrate bottom surface and a substrate upper surface and including a recess in the substrate bottom surface;
a semiconductor element provided above the recess; and
a first electrode provided in the recess,
wherein the recess includes a recess side surface and a recess upper surface, an angle formed between the recess side surface and the recess upper surface being 90 degrees or more, and
a film thickness of the first electrode is 1/2 or more of a depth of the recess.

2. The semiconductor device according to claim 1, wherein the film thickness of the first electrode is longer than a substrate thickness of a portion of the semiconductor substrate provided with the recess.

3. The semiconductor device according to claim 1, wherein the substrate thickness of the portion of the semiconductor substrate provided with the recess is 100 μm or shorter.

4. The semiconductor device according to claim 1, wherein a length of a portion of the substrate bottom surface not provided with the recess is 1/4 or less of a length of the substrate upper surface.

5. The semiconductor device according to claim 1, wherein the first electrode is provided over the recess upper surface, the recess side surface, and the substrate bottom surface.

6. The semiconductor device according to claim 5, wherein the film thickness of the first electrode is longer than twice a film thickness of a portion of the first electrode contacting the substrate bottom surface.

7. The semiconductor device according to claim 5, wherein a bottom surface of the first electrode is parallel to the substrate upper surface.

8. The semiconductor device according to claim 1, wherein the first electrode includes a first layer containing a first element and a second layer provided on the first layer and containing a second element different from the first element.

9. The semiconductor device according to claim 8, wherein the first electrode further includes a third layer provided between the first layer and the second layer and containing titanium (Ti) or tantalum (Ta).

10. The semiconductor device according to claim 1, wherein the first electrode includes a barrier metal at a portion of the first electrode contacting the recess side surface and the recess upper surface.

11. The semiconductor device according to claim 1, wherein the recess upper surface is parallel to the substrate upper surface.
